(19) United States
(12) Patent Application Publication
(10) Pub. No.: US 2025/0389792 A1
(43) Pub. Date: Dec. 25, 2025

(54) Chip Ground Detection Device and Methods

(71) Applicant: Robert Bosch GmbH, Stuttgart (DE)

(72) Inventors: Xiaofei Qiu, Suzhou (CN); David Voigt, Bietigheim-Bissingen (DE)

(21) Appl. No.: 19/246,535

(22) Filed: Jun. 23, 2025

(30) Foreign Application Priority Data
Jun. 24, 2024 (CN) 2024 1082 2125.6

(51) Int. Cl. G01R 31/52; B60R 21/01; G01R 27/02; G01R 31/00

(52) U.S. Cl. CPC G01R 31/52; B60R 21/01; G01R 27/02; G01R 31/007; B60R 2021/01184; B60R 2021/01286

(57) ABSTRACT

A chip ground detection device includes (i) a current source, (ii) a switching device including one or more switching units, (iii) a voltage monitoring unit coupled to an exposed pad of a chip via the one or more switching units, and (iv) a control unit for controlling the one or more switching units and configured to close the one or more switching units when the current source is operating, such that the voltage monitoring unit obtains a first voltage V₁ on the exposed pad; is configured to close the one or more switching units when the current source is not operating, such that the voltage monitoring unit obtains a second voltage V₂ on the exposed pad; and determines a ground resistance for the exposed pad based on the first voltage V₁ and the second voltage V₂ . An application-specific integrated circuit chip, a method of chip ground detection, and a computer program product are also disclosed.

This application claims priority under 35 U.S.C. § 119 to application no. CN 2024 1082 2125.6, filed on Jun. 24, 2024 in China, the disclosure of which is incorporated herein by reference in its entirety.

The present application relates to the field of chip ground detection, more particularly, to a chip ground detection device, an application-specific integrated circuit chip for the airbag electronics control unit ECU, a method for chip ground detection, and computer program products.

### BACKGROUND

In an electronic control unit system (e.g., an airbag ECU), an application-specific integrated circuit chip ASIC is used to provide ignition loop drivers, PSI interfaces, power supplies, etc. In order to save the pins of the application-specific integrated circuit chip ASIC, the low-power-level circuit coupled to the ignition resistor is generally connected to the exposed pad (EPAD) at the bottom of the chip, while the exposed pad EPAD further coupled to the grounding copper plate of the PCB to achieve grounding.

If the exposed pad EPAD connection between the application-specific integrated circuit chip ASIC and the printed circuit board PCB is poor, it may cause many problems, including (1) the ignition current is insufficient to open the airbag; (2) the drive voltage cannot open the low-power-level circuit, such that the airbag cannot be deployed.

In the prior art, to promptly monitor the grounding condition of the chip, X-ray inspection is typically required in the factory to detect EPAD GND solder connection. However, this existing solution cannot cover field application faults, making it difficult to promptly eliminate safety risks.

### SUMMARY

The inventors of the present application recognize that all internal grounding of a chip (e.g., an application-specific integrated circuit chip ASIC in an airbag ECU) is connected to a grounding copper plate located below the chip and within a PCB of the printed circuit board via an exposed pad EPAD. Grounding of exposed pad EPAD can be characterized by its equivalent resistance (i.e., ground resistance), which indicates a fault in the chip's grounding when the grounding resistance is greater than a preset threshold.

According to one aspect of the present application, a chip ground detection device is proposed, the chip ground detection device comprising: a current source for providing a detection current to the chip ground detection device; a switching device comprising one or more switching units; a voltage monitoring unit coupled to an exposed pad EPAD of the chip via the one or more switching units, wherein the exposed pad EPAD coupled between the chip and ground; and a control unit for controlling the one or more switching units and configured to close the one or more switching units when the current source is operating, such that the voltage monitoring unit obtains the first voltage V₁ on the exposed pad EPAD; is configured to close one or more switching unit when the current source is not operating, such that the voltage monitoring unit obtains the second voltage V₂ on the exposed pad EPAD; and determines a ground resistance for the exposed pad EPAD based on the first voltage V₁ and the second voltage V₂.

As a supplement or alternative to the above solution, in the chip ground detection device described above, the chip is an application-specific integrated circuit chip.

As a supplement or alternative to the above solution, in the chip ground detection device described above, the switching device includes a first switching unit, a second switching unit and a third switching unit, wherein one end of the first switching unit is coupled with one end of the ignition resistor, the other end of the first switching unit is coupled with the voltage monitoring unit, one end of the second switching unit is coupled with the other end of the ignition resistor, the other end of the second switching unit is coupled with the voltage monitoring unit, one end of the third switching unit is coupled with the exposed pad EPAD, and the other end of the third switching unit is coupled with the voltage monitoring unit.

As a supplement or alternative to the above solution, in the chip ground detection device described above, the switching device further comprises: a fourth switching unit for controlling the current source.

As a supplement or alternative to the above solution, in the chip ground detection device described above, the control unit is configured to determine the ground resistance of the exposed pad EPAD according to the following formula:

$$R = \frac{{V}_{1} - {V}_{2}}{{I}_{diagnosis}} ,$$

wherein R is the ground resistance, V₁ is the first voltage, V₂ is the second voltage, and Idiagnosis provides the detection current for the current source.

As a supplement or alternative to the above solution, in the chip ground detection device described above, the grounding of the chip is faulty when the grounding resistance is greater than a preset threshold.

As a supplement or alternative to the above solution, in the chip ground detection device described above, the control device is further configured to: closing the first switching unit, opening the second switching unit and the third switching unit when the current source is operating, such that the voltage monitoring unit obtains a high-power-level side voltage VHS of the ignition resistor, and closing the second switching unit, opening the first switching unit and the third switching unit when the current source is operating,

such that the voltage monitoring unit obtains a low-power-level side voltage V_{LS} of the ignition resistor.

As a supplement or alternative to the above solution, in the chip ground detection device described above, the control device is further configured to: determining a resistance of the ignition resistor based on the high-power-level side voltage V_{LS} and the low-power-level side voltage V_{LS}.

In accordance with another aspect of the present application, a application-specific integrated circuit chip for a airbag electronics control unit ECU is presented that comprises: a high-power-level circuit (which may include a first current regulation circuit), coupled between a power supply and an ignition resistor; a low-power-level circuit (which may include a second current regulation circuit), coupled between the ignition resistor and the exposed pad EPAD of the chip; and a chip ground detection device as described above for determining the grounding resistance of the exposed pad EPAD.

According to yet another aspect of the present application, a method for chip ground detection using the chip ground detection device as described above is proposed, the method comprising: closing the third switching unit and the fourth switching unit, while opening the first switching unit and the second switching unit simultaneously, and utilizing the voltage monitoring unit to obtain the first voltage V₁ on the exposed pad EPAD; closing the third switching unit, while opening the first switching unit, the second switching unit, and the fourth switching unit simultaneously, and utilizing the voltage monitoring unit to obtain the second voltage V₂ on the exposed pad EPAD; and determines a ground resistance for the exposed pad EPAD based on the first voltage V₁ and the second voltage V₂.

According to yet another aspect of the present application, a computer program product comprising a computer program, which, when executed by a processor, performs the chip ground detection method as described above.

The chip ground detection solution of the embodiments of the present application can detect the ground situation of the exposed pad EPAD in a timely manner and can cover field applications, thereby avoiding potential safety hazards.

### BRIEF DESCRIPTION OF THE DRAWINGS

The foregoing and other objectives and advantages of the present application will become more fully apparent from the following detailed description taken in conjunction with the accompanying drawings, in which identical or similar elements are denoted by the same reference numerals.

FIG. 1 illustrates a structural schematic diagram of a chip ground detection device according to one embodiment of the present application;

FIG. 2 illustrates a structural schematic diagram of an application-specific integrated circuit chip for the airbag electronic control unit ECU according to one embodiment of the present application;

FIG. 3 illustrates a schematic diagram of an ignition circuit of an application-specific integrated circuit chip

for the airbag electronic control unit ECU according to one embodiment of the present application; and

FIG. 4 illustrates a method for chip ground detection based on chip ground detection device according to one embodiment of the present application.

### DETAILED DESCRIPTION

In the following, chip ground detection solution according to various exemplary embodiments of the present application will be described in detail with reference to the accompanying drawings.

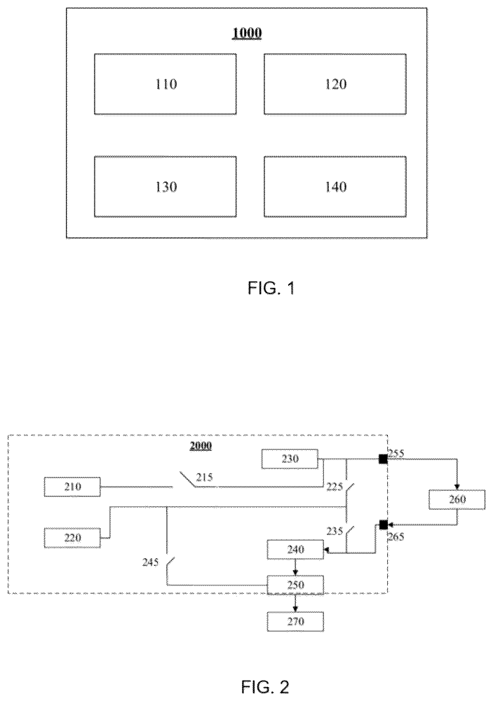

FIG. 1 illustrates a schematic diagram of a chip ground detection device 1000, according to one embodiment of the present application. As shown in FIG. 1, the chip ground detection device 1000 comprises: A current source 110 is used to provide a detection current for the chip ground detection device 1000; a switching device 120 including one or more switching units; a voltage monitoring unit 130, the voltage monitoring unit 130 is coupled to the exposed pad EPAD of the chip via one or more switching units in the switching device 120, wherein the exposed pad EPAD is coupled between the chip and ground; and a control unit 140 for controlling one or more switching units in the switching device 120 and is configured to close one or more switching units in the switching device 120 when the current source 110 is operating, such that the voltage monitoring unit 130 obtains the first voltage V₁ on the exposed pad EPAD; and is configured to close one or more switching units in the switching device 120 when the current source 110 is not operating (for example, when it is disconnected from the chip ground detection device 1000), such that the voltage monitoring unit 130 obtains the second voltage V₂ on the exposed pad EPAD; and determines the ground resistance of the exposed pad EPAD based on the first voltage V₁ and the second voltage V₂.

In the context of the present application, the exposed pad (EPAD) is a connection point of the chip, where all internal grounding of the chip is connected to the centroid point below the device. The design of exposed pad EPAD has an important impact on the performance of the signal chain and the adequate heat dissipation of the device. In some cases, the exposed pad EPAD is also referred to as pin 0. When designing, attention needs to be paid to the layout and connection of EPAD to ensure the stability and reliability of the electrical and thermal connections.

In addition, the term “ground resistance” is used to characterize grounding situation of exposed pad EPAD. It can be understood that the resistance value of the ground resistance is 0 ohm or near 0 ohm in the case of a well grounded exposed pad EPAD.

In one embodiment, the aforementioned chip is an application-specific integrated circuit chip. The so-called “application-specific integrated circuit chip,” also known as Application Specific Integrated Circuit (ASIC), is a custom integrated circuit designed and manufactured by a specific user or by the needs of a specific electronic system, typically with higher performance and lower power consumption than a general purpose integrated circuit. In addition, ASIC can integrate a large number of logic gates, memory, analog circuits, etc., on a single chip to achieve a high degree of integration.

In one embodiment, although not shown in FIG. 1, the switching device 120 may include a first switching unit, a second switching unit, and a third switching unit, wherein one end of the first switching unit is coupled with one end of the ignition resistor, the other end of the first switching unit is coupled with the voltage monitoring unit 130, one end of the second switching unit is coupled with one end of the ignition resistor, the other end of the second switching unit is coupled with the voltage monitoring unit 130, and one end of the third switching unit is coupled with the exposed pad EPAD, the other end of the third switching unit is coupled with the voltage monitoring unit 130. In one embodiment, the switching device 120 further comprises: A fourth switching unit for controlling the current source 110.

In one embodiment, the control unit 140 is configured to determine the ground resistance of the exposed pad EPAD according to the following equation:

$$R = \frac{{V}_{1} - {V}_{2}}{{I}_{diagnosis}} ,$$

wherein R is the ground resistance, V₁ is the first voltage, V₂ is the second voltage, and Idiagnosis provides a detection current for the current source “0. It will be understood that the grounding of the chip is faulty when the grounding resistance is greater than a preset threshold.

In one embodiment, the control unit 140 is further configured to: closing the first switching unit, opening the second switching unit and the third switching unit when the current source 110 is operating, such that the voltage monitoring unit 130 obtains a high-power-level side voltage VHS of the ignition resistor, and closing the second switching unit, opening the first switching unit and the third switching unit when the current source 110 is operating, such that the voltage monitoring unit 130 obtains a low-power-level side voltage V_{LS} of the ignition resistor. In the present embodiment, the control unit 140 is further configured to: determining a resistance of the ignition resistor based on the high-power-level side voltage VHS and the low-power-level side voltage V_{LS}. Accurately measuring the resistance of the ignition resistor helps ensure that the safety airbag can ignition in a timely and accurate manner.

Referring to FIG. 2, it illustrates a structural schematic diagram of an application-specific integrated circuit chip 2000 (which includes a chip ground detection device) for an airbag electronic control unit ECU according to one embodiment of the present application. Similar to FIG. 1, the application-specific integrated circuit chip 2000 of FIG. 2 includes: a current source 210, a voltage monitoring unit 220, a first switching unit 225, a second switching unit 235, and a third switching unit 245.

In the embodiment of FIG. 2, the first switching unit 225, the second switching unit 235, and the third switching unit 245 function as a “switching device.” As shown in FIG. 2, one end of the first switching unit 225 is coupled to one end of the ignition resistor 260 (refer to connection point 255 in FIG. 2), and the other end of the first switching unit is coupled to the voltage monitoring unit 220, one end of the second switching unit 235 is coupled to the other end of the ignition resistor 260 (refer to connection point 265 in FIG. 2), and the other end of the second switching unit 235 is coupled to the voltage monitoring unit 220, and one end of the third switching unit 245 is coupled to the exposed pad EPAD 250 (the exposed pad EPAD 250 is further connected to ground 270, such as a grounding copper plate on the PCB), and the other end of the third switching unit 245 is coupled to the voltage monitoring unit 220.

With further reference to FIG. 2, in one embodiment, the switching device may further comprise a fourth switching unit 215 for controlling the current source 210. It will be understood that when the fourth switching unit is closed, the current source 210 operates, that is, provides current to the chip ground detection device; and when the fourth switching unit is opened, the current source 210 is not operational.

In addition to the chip ground detection device, the application-specific integrated circuit chip 2000 of FIG. 2 further comprises: High-power-level circuit 230 (also referred to as first-power-level circuit 230, which may include a first current regulation circuit), coupled between a power supply (not shown in FIG. 2) and ignition resistor 260; low-power-level circuit 240 (also referred to as second-power-level circuit 240, which may include a second current regulation circuit), coupled between the ignition resistor 260 and exposed pad EPAD 250.

In the context of the present application, the high-power-level circuit 230 is used to process the circuit portion of the higher current or power and the low-power-level circuit 240 is used to process the circuit portion of the lower current or power.

The concepts of “high-power-level circuit 230” (also referred to as first-power-level circuit 230) and “low-power-level circuit 240” (also referred to as second-power-level circuit 240) are opposed. In one embodiment, the high-power-level circuit 230 may include a first semiconductor transistor and a first current regulation circuit (not shown in FIG. 2) for controlling the current flowing into the connection point 255 (i.e. the ignition resistor 260 high-power-level side current). In one embodiment, the low-power-level circuit 240 may include a second semiconductor transistor and a second current regulation circuit for controlling the current flowing out of the connection point 265 (i.e. the low-power-level side current of the ignition resistor 260).

In one or more embodiments, the ignition resistor 260 is a critical component used to control the flow of current during the airbag inflating process. The airbag electronic control unit ECU shall be responsible for data collection and data processing and the reliability of diagnostic airbags, and when the preset value is reached, ignition signal shall be sent in a timely manner. This ignition signal generates a large amount of gas by triggering the gas generator through ignition resistor 260 to inflate the airbag and protect the passenger. In addition, ignition resistor 260 also helps prevent electrical noise and false triggers, increasing the safety and reliability of airbag systems.

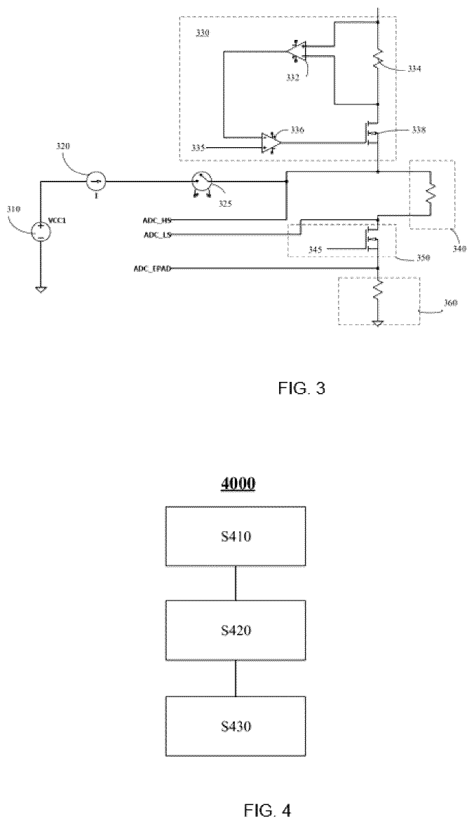

FIG. 3 illustrates a schematic diagram of an ignition circuit in an application-specific integrated circuit chip for a airbag electronics control unit ECU according to one embodiment of the present application. As shown in FIG. 3, the voltage source 310 (e.g., 6.7V) and the current source 320 form a power supply circuit in series to power the entire ignition circuit.

One end of the switching device 325 is coupled with the current source 320 and the other end is coupled with the ignition resistor 340 to control the power supply to the power circuit. The high-power-level circuit 330 is coupled between the power supply (not shown in FIG. 3) and the ignition resistor 340, and the low-power-level circuit 350 is coupled between the ignition resistor 340 and the exposed pad EPAD 360.

Continuing with reference to FIG. 3, the high-power-level circuit 330 includes a first transistor 338 and a first current regulation circuit (consisting of a sense resistor 334, a first operational amplifier 332, and a second operational amplifier 336) that collectively control the ignition resistor 340 high-power-level side current. As can be seen from FIG. 3, one end of the sense resistor 334 is coupled to the non-inverting input of the first operational amplifier 332, the other end of the sense resistor 334 is coupled to the inverting input of the first operational amplifier 332, and the output end of the first operational amplifier 332 is coupled to the inverting input of second operational amplifier 336, the non-inverting input of the second operational amplifier 336 is coupled to the reference voltage 335, and the output of the second operational amplifier 336 is coupled to the gate of the first transistor 338 (for example, NMOS), the drain of the first transistor 338 is coupled to the inverting input of the first operational amplifier 332, the source of the first transistor 338 is coupled with one side of the ignition resistor 340.

It will be understood that when a current passes through the sense resistor 334, a voltage drop will occur at both ends of the sense resistor 334 and the voltage drop input to the operational amplifier 332 is operationally amplified and output to the inverting input of the second operational amplifier for comparison with the reference voltage 335 (coupled to the non-inverting input of the second operational amplifier) to provide the first transistor 338. When the gate input voltage of the first transistor 338 is below the turn-on threshold of the first transistor 338, the first transistor 338 is in the cut-off state, at which point the current in the loop cannot flow into the ignition resistor 340 via the first transistor 338. And when the gate input voltage of the first transistor 338 is above the turn-on threshold for the first transistor 338, the first transistor 338 is in the conductive state.

At this point, the current in the loop can flow through the first transistor 338 into the ignition resistor 340. As such, the current flowing through the ignition resistor 340 may be adjusted by properly adjusting the reference voltage 335.

In FIG. 3, the low-power-level circuit 350 includes a second transistor having a grid coupled to a low-side drive signal 345, a drain of the second transistor coupled to an ignition resistor 340, and a source of the second transistor being grounded via an exposed pad EPAD 360. It will be understood that if the ground condition of the exposed pad EPAD 360 is poor, i.e., when the ground resistance is too large, the current flowing through the ignition resistor 340 will become small (this current is also referred to as “ignition current”), which may cause the airbag to not open normally. Moreover, when the ground resistance is too large, the source extreme voltage of the second transistor is not 0, causing the low-side drive signal 345 (drive voltage) to fail to turn on the second transistor, rendering the airbag unexpandable.

To detect the grounding of the exposed pad EPAD 360, the current source 320 can be caused to provide diagnostic current to the ignition resistor 340 by closing the switching device 325, while placing the first transistor 338 in the cut-off state, so that other currents do not flow to the ignition block 340 via the high-power-level circuit 330. Next, the second transistor is placed in a conductive state by the low-side drive signal 345. The voltage acquisition unit may then be utilized to obtain the ignition resistor 260 high-power-level side voltage ADC_HS, the ignition resistor 260 low-power-level side voltage ADC_LS, and the voltage ADC_EPAD on the exposed pad EPAD 360 (i.e. the first voltage V₁). The switching device 325 is then turned off to disable the current source 320, i.e., to not provide diagnostic current to the ignition resistor 340. At this time, utilizing the voltage to obtain the voltage ADC_EPAD on the unit exposed pad EPAD 360 (which is the second voltage V₂).

In one or more embodiments, the ground resistance of the exposed pad EPAD 360 may be determined according to the following formula:

$$R = \frac{{V}_{1} - {V}_{2}}{{I}_{diagnosis}} ,$$

where R is the ground resistance, V₁ is the first voltage (i.e., the voltage measured on the exposed pad EPAD 360 when the current source 320 provides a diagnosis interrupt current), V₂ is the second voltage (i.e., the voltage measured on the exposed pad EPAD 360 when the electrical flow source 320 does not provide a diagnostic current), and Idiagnosis provides the detection current source 320. It will be understood that the grounding of the chip is at fault when the grounding resistance is greater than the preset threshold.

In addition, the obtained high-power-level side voltage ADC_HS, low-power-level side voltage ADC_LS may be used for ignition resistor testing to accurately determine the resistance of the ignition resistor 340 (which is also important for the safety of the safe airbag).

FIG. 4 illustrates a method 4000 of chip ground detection based on a chip ground detection device according to one embodiment of the present application. In combination with FIGS. 2 and 4, the method 4000 comprises the following steps:

In step S410, closing the third switching unit 245 and the fourth switching unit 215, while opening the first switching unit 225 and the second switching unit 235 simultaneously, and utilizing the voltage monitoring unit 220 to obtain the first voltage V₁ on the exposed pad EPAD 250;

In step S420, closing the third switching unit 245 while opening the first switching unit 225, the second switching unit 235, and the fourth switching unit 215 simultaneously, and utilizing the voltage monitoring unit 220 to obtain the second voltage V₂ on the exposed pad EPAD 250; and

In step S430, the ground resistance of the exposed pad EPAD 250 is determined based on the first voltage V₁ and the second voltage V₂.

In one or more embodiments, step S430 includes determining a ground resistance of the exposed pad EPAD 250 according to the following formula:

$$R = \frac{{V}_{1} - {V}_{2}}{{I}_{diagnosis}} ,$$

wherein R is the ground resistance and Idiagnosis provides a detection current for the current source. When the determined ground resistance is greater than a preset threshold, the grounding of the chip is at fault.

In addition, it will be readily understood by those skilled in the art that the method 4000 of chip ground detection shown in FIG. 4 can be implemented by a computer program. For example, the computer program is included in a computer program product that implements the method 4000 for chip ground detection. For example, when a computer-readable storage medium (e.g., a U-disk) containing the computer program is connected to the computer, the method 4000 of executing the computer program may perform the chip ground detection.

The examples above mainly illustrate a chip ground detection solution provided in the embodiments of the present application. Although only some of the examples of the present application have been described, it should be understood by those with ordinary skill in the art that the present application may be implemented in various other forms without departing from its spirit and scope. Therefore, the examples and embodiments presented are illustrative rather than limiting, and the present application may encompass various modifications and replacements without departing from the spirit and scope defined by the various claims.

What is claimed is:

1. A chip ground detection device, comprising:
a current source configured to provide a detection current for the chip ground detection device;
a switching device including one or more switching units;
a voltage monitoring unit coupled to an exposed pad EPAD of a chip via the one or more switching units, wherein the exposed pad EPAD is coupled between the chip and ground; and
a control unit configured to control the one or more switching units and configured to close the one or more switching units when the current source is operating, such that the voltage monitoring unit obtains a first voltage on the exposed pad EPAD; is configured to close the one or more switching units when the current source is not operating, such that the voltage monitoring unit obtains a second voltage on the exposed pad EPAD; and determines a ground resistance for the exposed pad EPAD based on the first voltage and the second voltage.

2. The chip ground detection device according to claim 1, wherein the chip is an application-specific integrated circuit chip.

3. The chip ground detection device according to claim 1, wherein the switching device includes a first switching unit, a second switching unit and a third switching unit, and wherein one end of the first switching unit is coupled with one end of an ignition resistor, the other end of the first switching unit is coupled with the voltage monitoring unit, one end of the second switching unit is coupled with the other end of the ignition resistor, the other end of the second switching unit is coupled with the voltage monitoring unit, one end of the third switching unit is coupled with the exposed pad EPAD, and the other end of the third switching unit is coupled with the voltage monitoring unit.

4. The chip ground detection device according to claim 3, wherein the switching device further comprises a fourth switching unit configured to control the current source.

5. The chip ground detection device according to claim 1, wherein the control unit is configured to determine the ground resistance of the exposed pad EPAD according to the following formula:
$$R = \frac{{V}_{1} - {V}_{2}}{{I}_{diagnosis}} ,$$
wherein R is the ground resistance, V₁ is the first voltage, V₂ is the second voltage, and I_{diagnosis} provides the detection current for the current source.

6. The chip ground detection device according to claim 1, wherein the grounding of the chip is faulty when the ground resistance is greater than a preset threshold.

7. The chip ground detection device according to claim 3, wherein the control unit is further configured to: close the first switching unit, open the second switching unit and the third switching unit when the current source is operating, such that the voltage monitoring unit obtains a high-power-level side voltage of the ignition resistor, and close the second switching unit, open the first switching unit and the third switching unit when the current source is operating, such that the voltage monitoring unit obtains a low-power-level side voltage of the ignition resistor.

8. The chip ground detection device according to claim 7, wherein the control unit is further configured to determine a resistance of the ignition resistor based on the high-power-level side voltage and the low-power-level side voltage.

9. An application-specific integrated circuit chip for an airbag electronics control unit, comprising:
a high-power-level circuit coupled between a power supply and an ignition resistor;
a low-power-level circuit coupled between the ignition resistor and an exposed pad EPAD of the chip; and
the chip ground detection device according to claim 1, used to determine the ground resistance of the exposed pad EPAD.

10. A method of utilizing a chip ground detection device for chip ground detection according to claim 4, the method comprising:
closing the third switching unit and the fourth switching unit, while opening the first switching unit and the second switching unit simultaneously, and utilizing the voltage monitoring unit to obtain the first voltage on the exposed pad EPAD;
closing the third switching unit, while opening the first switching unit, the second switching unit, and the fourth switching unit simultaneously, and utilizing the voltage monitoring unit to obtain the second voltage on the exposed pad EPAD; and
determining a ground resistance of the exposed pad EPAD based on the first voltage and the second voltage.

11. A computer program product, comprising a computer program, wherein the computer program, when executed by a processor, implements the method according to claim 10.
